(19) United States
(12) Patent Application Publication
(10) Pub. No.: US 2014/0211413 A1
(43) Pub. Date: Jul. 31, 2014

(54) ELECTRONIC DEVICE WITH HEAT DISSIPATION DEVICE

(71) Applicants: HONG FU JIN PRECISION INDUSTRY (ShenZhen) CO., LTD., (US); HON HAI PRECISION INDUSTRY CO., LTD., New Taipei (TW)

(72) Inventors: Lei LIU, Shenzhen (CN); Guo-Yi CHEN, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/771,036

(22) Filed: Feb. 19, 2013

(30) Foreign Application Priority Data
Jan. 28, 2013 (CN) 201310031022.X

(51) Int. Cl. H05K 7/20

(52) U.S. Cl. CPC H05K 7/20172
USPC 361/679.48; 361/695

(57) ABSTRACT

An electronic device includes a chassis, a fan, and a frame. The chassis includes a bottom wall and a sidewall mounted to the bottom wall. The fan includes two opposite ends boards. Each end board defines four through holes in four corners. The frame includes a supporting member and a fixing member connected to an end of the supporting member. The supporting member includes two bars to support the fan. One of the bars defines a slide slot. Two screws extend through two adjacent through holes of the fan and the slide slot, and then engaged in two nuts. Two screws extend through the fixing member, and then engaged in the sidewall.

### BACKGROUND

1. Technical Field

The present disclosure relates to an electronic device having a heat dissipation device.

2. Description of Related Art

A plurality of electronic components, such as expansion cards or memory cards, is often added into servers to expand the capacity of the servers. These cards generate a great amount of heat, which cannot be dissipated properly by the original heat dissipation systems of the servers.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device.

FIG. 2 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

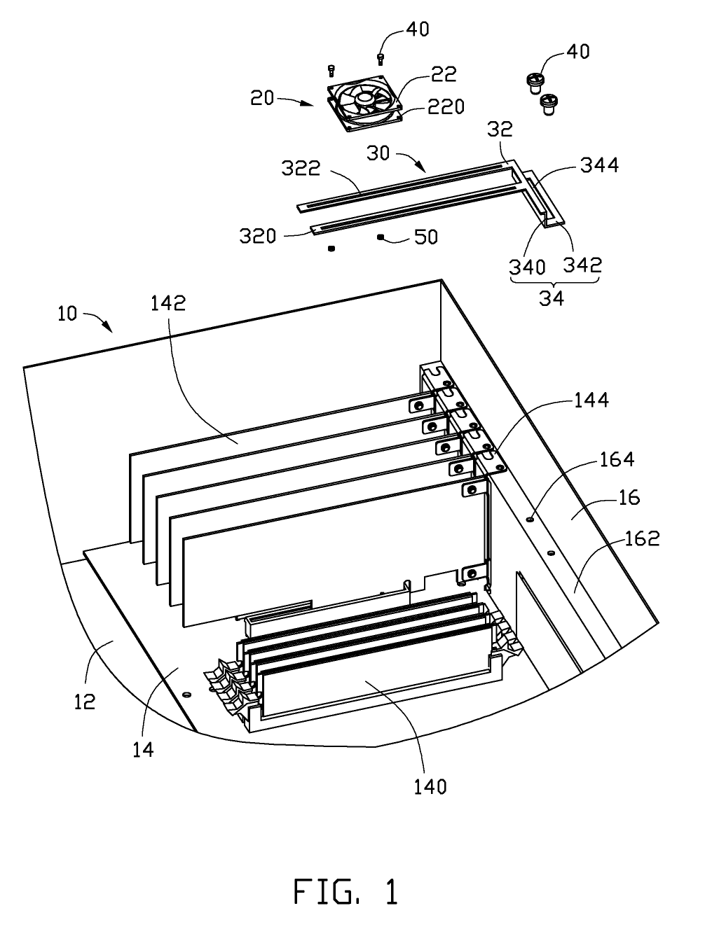

Referring to FIG. 1, an embodiment of an electronic device includes a chassis 10, a fan 20, a frame 30, a plurality of screws 40, and two nuts 50.

The chassis 10 includes a bottom wall 12, a motherboard 14 mounted on the bottom wall 12, a sidewall 16 connected substantially perpendicularly to a side of the bottom wall 12. An installation board 162 substantially parallel to the motherboard 14 extends substantially perpendicularly from an inner surface of the sidewall 16 and longitudinally defines a plurality of fixing holes 164. A memory card group 140 and a plurality of expansion cards 142 are mounted substantially perpendicularly on the motherboard 14. A plurality of L-shaped fixing portions 144 fixed to ends of the expansion cards 142 is fixed to the installation board 162.

The fan 20 includes two opposite end boards 22. Each end board 22 defines four through holes 220 in four corners, respectively.

The frame 30 includes a supporting member 32 and an L-shaped fixing member 34 connected to an end of the supporting member 32. The supporting member 32 includes two substantially parallel bars 320 each longitudinally defining a slide slot 322. The fixing member 34 includes an extension piece 340 extending substantially perpendicularly down from the end of the supporting member 32 and a fixing piece 342 extending substantially perpendicularly from a bottom side of the extension piece 340 away from the supporting member 32. The fixing piece 342 longitudinally defines a groove 344 substantially perpendicular to the slide slots 322.

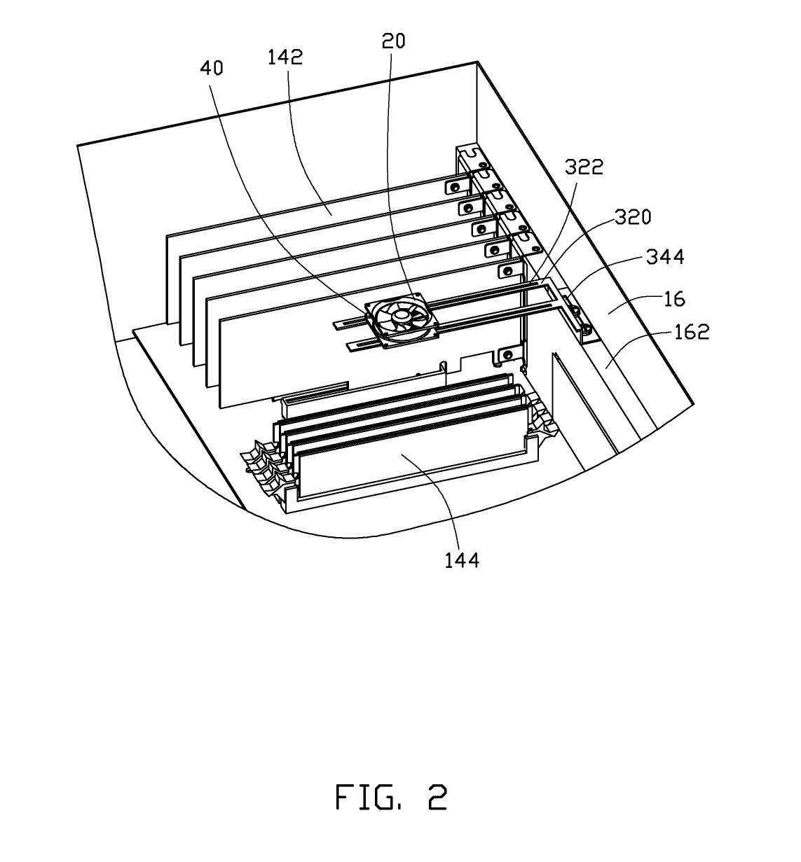

Referring to FIG. 2, in assembly, two screws 40 extend through the groove 344 and engage in two of the fixing holes 164, thereby fixing the frame 30 in the chassis 10 and above the memory card group 140. The bars 320 are substantially parallel to the motherboard 14.

Two screws 40 extend through two adjacent through holes 220 and one of the slide slots 322, and then engage in two nuts 50, thereby fixing the fan 20 to the frame 30 and above the memory card group 140 to dissipate heat generated by the memory card group 140. At this time, the other bar 320 supports the fan 20. Before the screws 40 extending through the fan 20 are fastened, the fan 20 can be slid along the slide slots 322 to be fixed in a desired position.

The frame 30 can be used to fix fans having different sizes. In another embodiment, four screws 40 can extend through the through holes 22 of an end board 22 of a fan having a small size, the slide slots 322, and then engage in four nuts 50.

In another embodiment, two screws 40 can extend through the groove 344 and two of the fixing portions 144, and then engage in the installation board 162, thereby fixing the frame 30 and two corresponding expansion cards 142 to the installation board 162, to allow the fan 20 to dissipate heat generated by the expansion cards 142.

It is believed that the present embodiments and their advantages will be understood from the foregoing description, and various changes may be made thereto without departing from the spirit and scope of the description or sacrificing all of their material advantages, the examples hereinbefore described merely being embodiments.

What is claimed is:

1. An electronic device, comprising:
a chassis comprising a bottom wall and a sidewall mounted to the bottom wall;
a fan comprising two opposite end boards each defining four through holes in four corners;
a frame comprising a supporting member supporting the fan, and a fixing member connected to an end of the supporting member, the supporting member comprising two bars, at least one of the bars defining a slide slot; and
a plurality of screws, wherein two screws of the plurality of screws extend through two adjacent through holes of the fan, the slide slot, and then engage in two nuts; at least one of the plurality of screws extend through the fixing member and engage in the sidewall.

2. The electronic device of claim 1, wherein the fixing member comprises an extension piece connected substantially perpendicularly to the supporting member, and a fixing piece extending substantially perpendicularly from the extension piece away from the supporting member, the fixing piece defines a groove substantially perpendicular to the slide slot, an installation board extends substantially perpendicularly from the sidewall, and the two screws extend through the groove and engage in the installation board.

3. An electronic device, comprising:
a chassis comprising a bottom wall and a sidewall extending up from the bottom wall;
a motherboard mounted on the bottom wall;
a plurality of heat-generating elements mounted on the motherboard;
a fan; and
a frame comprising a supporting member extending from the sidewall and located above the plurality of heat-generating elements, wherein the supporting member is apart from the motherboard and supporting the fan.

4. The electronic device of claim 3, wherein the supporting member comprises a bar substantially parallel to the motherboard, and the fan is mounted on the bar.

5. The electronic device of claim 4, wherein a lengthwise direction of the bar is substantially perpendicular to the sidewall.

6. The electronic device of claim 3, wherein a slide slot is longitudinally defined in the bar, and a fastener extends through the fan and the slide slot, and engages in a nut.

7. The electronic device of claim 3, wherein the plurality of heat-generating elements is a plurality of memory cards substantially perpendicularly mounted on the motherboard.

8. The electronic device of claim 3, wherein the plurality of heat-generating elements is a plurality of expansion cards substantially perpendicularly mounted on the motherboard.
